(19) United States
(12) Patent Application Publication
(10) Pub. No.: US 2007/0035021 A1
(43) Pub. Date: Feb. 15, 2007

(54) Printed circuit board and electronic apparatus including printed circuit board

(76) Inventors: Daigo Suzuki, Yokohama-shi (JP); Kuniyasu Hosoda, Hanno-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/499,097

(22) Filed: Aug. 4, 2006

(30) Foreign Application Priority Data
Aug. 10, 2005 (JP) 2005-232403

(51) Int. Cl. H01L 23/48; H01L 23/52; H01L 29/40

(52) U.S. Cl. 257/737

(57) ABSTRACT

According to one embodiment, a printed circuit board includes a printed wiring board, a semiconductor package, an adhesive and a stepped portion. The printed wiring board has a plurality of pads. The semiconductor package has a plurality of connection terminals corresponding to the pads and is mounted on the printed wiring board by soldering the connection terminals to the pads. The adhesive is filled between an outer peripheral portion of the semiconductor package and the printed wiring board and fixes the semiconductor package to the printed wiring board. The stepped portion divides an area between the semiconductor package and the printed wiring board into a first region, to which a solder for bonding the connection terminal and the pad is supplied, and a second region in which the adhesive is filled.

### CROSS-REFERENCE TO RELATED APPLICATIONS

This application is based upon and claims the benefit of priority from Japanese Patent Application No. 2005-232403, filed Aug. 10, 2005, the entire contents of which are incorporated herein by reference.

### BACKGROUND

1. Field

One embodiment of the invention relates to a printed circuit board on which a circuit component is mounted, and an electronic apparatus including the printed circuit board.

2. Description of the Related Art

For example, as a printed circuit board used in a portable computer, there is known a printed circuit board in which a BGA (Ball Grid Array) type semiconductor package is mounted on a printed wiring board. In this kind of printed circuit board, the semiconductor package is precisely connected to the printed wiring board via a plurality of solder balls. It is thus necessary to fix the semiconductor package to the printed wiring board with a predetermined strength secured. For this purpose, in the conventional printed circuit board, corner portions of the semiconductor package are fixed to the printed wiring board via a resin adhesive.

The adhesive is applied to two locations, that is, one side surface of a circuit component and another side surface of the circuit component, which is opposed to the one side surface. The locations where the adhesive is applied are adjacent to an area where solder is applied (see, for instance, Jpn. Pat. Appln. KOKAI Publication No. 2004-311898).

In the conventional printed circuit board, since the adhesive is applied adjacent to the solder, the adhesive may flow into the region to which the solder is supplied, depending on the amount or position of the applied adhesive. In usual cases, the thermal expansion coefficient of the resin adhesive is higher than that of solder which is a metal. Consequently, if expansion/contraction of the printed circuit board is repeated due to heat in the state in which the adhesive flows into the area of the solder, a crack may occur at the solder-bonded part due to a difference in thermal expansion coefficient.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the present invention;

FIG. 2 is an exemplary partially cut-out perspective view of a printed circuit board which is accommodated within a housing of the portable computer shown in FIG. 1;

FIG. 3 is an exemplary top view of the printed circuit board shown in FIG. 2;

FIG. 4 is an exemplary cross-sectional view of the printed circuit board shown in FIG. 3, taken along line F4-F4 in FIG. 3;

FIG. 5 is an exemplary top view of a printed circuit board according to a second embodiment of the present invention;

FIG. 6 is an exemplary cross-sectional view of the printed circuit board shown in FIG. 5, taken along line F6-F6 in FIG. 5;

FIG. 7 is an exemplary top view of a printed circuit board according to a third embodiment of the present invention;

FIG. 8 is an exemplary cross-sectional view of the printed circuit board shown in FIG. 7, taken along line F8-F8 in FIG. 7; and

FIG. 9 is an exemplary cross-sectional view of a printed circuit board according to a fourth embodiment of the invention.

### DETAILED DESCRIPTION

Various embodiments according to the invention will be described hereinafter with reference to the accompanying drawings. In general, according to one embodiment of the invention, a printed circuit board includes a printed wiring board, a semiconductor package, an adhesive and a stepped portion. The printed wiring board has a plurality of pads. The semiconductor package has a plurality of connection terminals corresponding to the pads and is mounted on the printed wiring board by soldering the connection terminals to the pads. The adhesive is filled between an outer peripheral portion of the semiconductor package and the printed wiring board and fixes the semiconductor package to the printed wiring board. The stepped portion divides an area between the semiconductor package and the printed wiring board into a first region, to which a solder for bonding the connection terminal and the pad is supplied, and a second region in which the adhesive is filled.

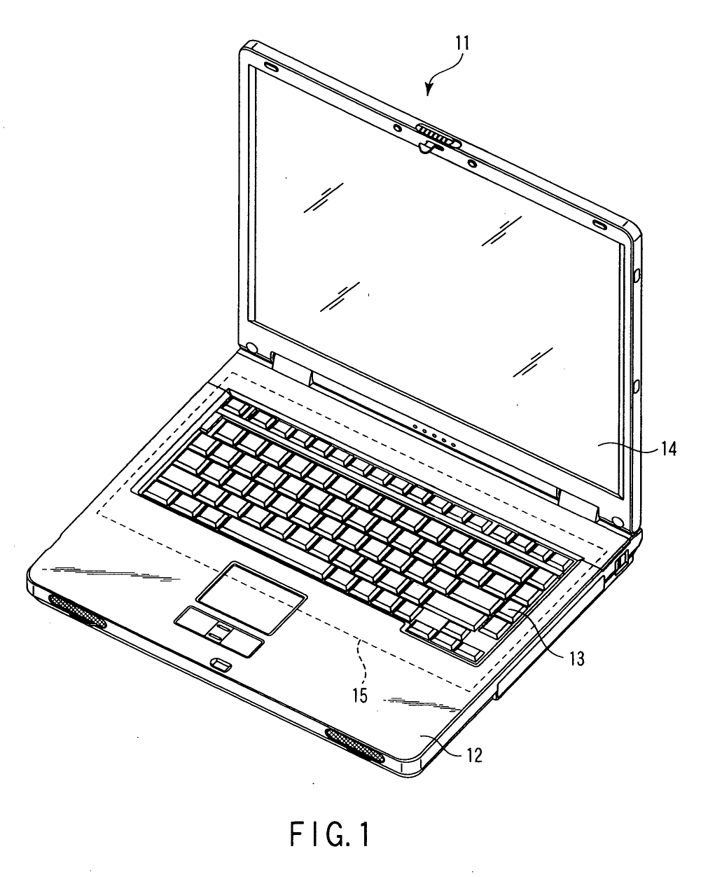

A first embodiment of an electronic apparatus of the present invention will now be described with reference to FIG. 1 to FIG. 4.

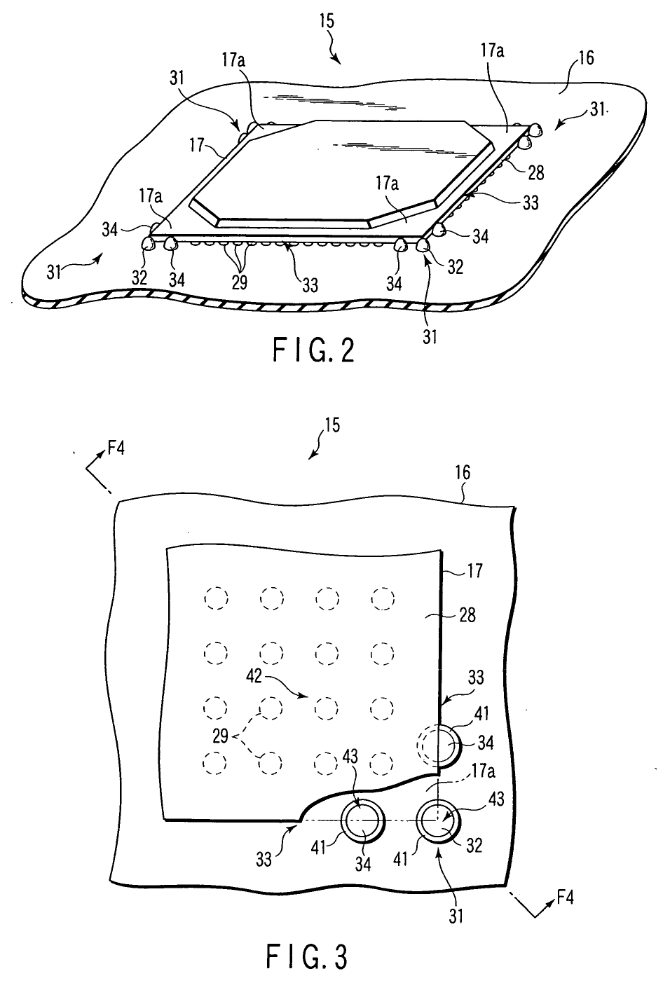

As is shown in FIG. 1, a portable computer 11, which is an example of the electronic apparatus, comprises a housing 12, a keyboard 13 and a display 14. The housing 12 accommodates a printed circuit board 15. As is shown in FIG. 2, the printed circuit board 15 includes a printed wiring board 16 and a BGA (Ball Grid Array) type semiconductor package 17.

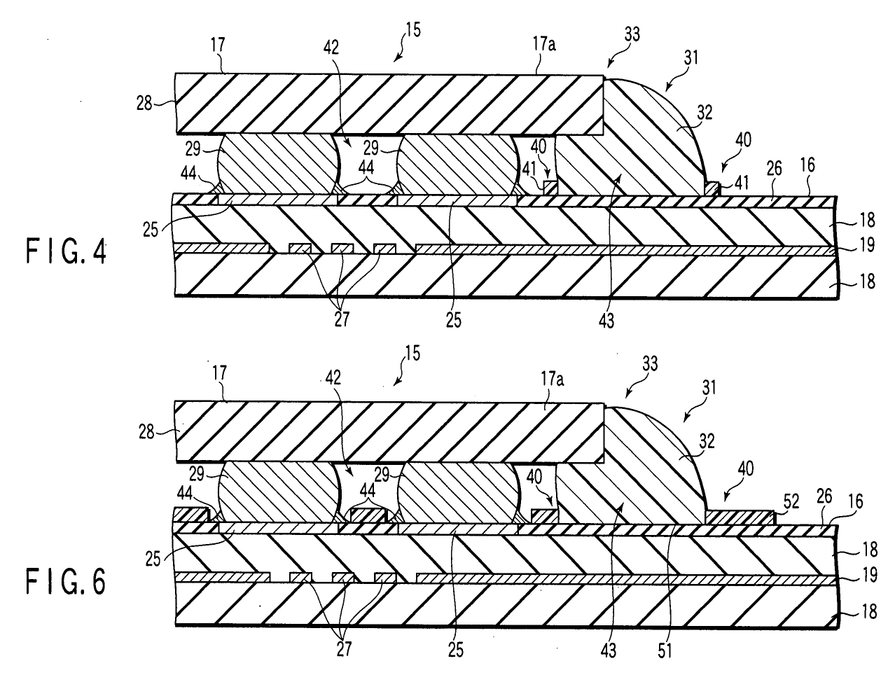

As is shown in FIG. 4, the printed wiring board 16 is composed of, e.g. a copper-clad laminate in which a copper wiring layer is stacked. The printed wiring board 16 comprises resin insulating layers 18 in which glass cloth that is used as base material is impregnated with resin; a wiring layer 19 interposed between the insulating layers 18; a plurality of pads 25 provided on an upper surface of the printed wiring board 16; and a solder resist layer 26 covering the surface of printed wiring board 16, except areas of the pads 25. The wiring layer 19 is formed on the lower-side insulating layer 18 with a predetermined pattern, for example, by etching a copper foil.

The pads 25 are plating that is provided in via holes (not shown) and are connected to, e.g. wiring lines 27 provided in an underlayer. The solder resist layer 26 is formed, for example, by printing solder resist on uppermost wiring (not shown).

The semiconductor package 17, as shown in FIG. 2, is an example of a circuit component, and is mounted on the printed wiring board 16. The semiconductor package 17 includes a package body 28 in which a semiconductor device (not shown) is resin-molded, and a plurality of solder balls 29 serving as connection terminals. The package body 28 has a square plate shape. The solder balls 29 are disposed in a grid fashion on a lower surface of the package body 28 so as to correspond to the associated pads 25. Thus, as shown in FIG. 4, connection parts between the solder balls 29 and pads 25 are located between the printed wiring board 16 and the semiconductor package 17.

As shown in FIG. 2, four corner portions 17a of the semiconductor package 17 are fixed to the printed wiring board 16 via an adhesive 31. The adhesive 31 is formed of, e.g. a thermosetting resin. The adhesive 31 fixes the package body 28 to the printed wiring board 16 such that each of the corner portions 17a of the semiconductor package 17 is fixed at three points to the printed wiring board 16. Specifically, the adhesive 31 includes a first adhesive element 32, which is provided to face the corner portion 17a of the semiconductor package 17, and a pair of second adhesive elements 34 which are provided adjacent to the first adhesive element 32. The second adhesive elements 34 are provided to face two sides of the semiconductor package 17, which neighbor the corner portion 17a.

The adhesive 31 is filled between an outer peripheral portion 33 of the semiconductor package 17 and the printed wiring board 16. As is shown in FIG. 3, the semiconductor package 17 is fixed to the printed wiring board 16 in the state in which the package body 28 is superposed on an upper-side ¼ of the first adhesive element 32. In addition, the semiconductor package 17 is fixed to the printed wiring board 16 in the state in which the package body 28 is superposed on an upper-side ½ of each second adhesive element 34.

As shown in FIG. 4, a stepped portion 40 is provided on the printed wiring board 16. In the present embodiment, the stepped portion 40 is defined by a projection 41 which is formed by silk screen printing on the printed wiring board 16. The projection 41 projects from the printed wiring board 16 toward the semiconductor package 17. The stepped portion 40, which is defined by the projection 41, divides the area between the semiconductor package 17 and the printed wiring board 16 into a first region 42 and a second region 43. A solder 44 for bonding the solder ball 29 and the pad 25 is supplied to the first region 42. The adhesive 31 is filled in the second region 43.

Next, the flow of the mounting process of the semiconductor package 17 is described. The semiconductor package 17 is picked up by an automated mounter, and is then mounted on the upper surface of the printed wiring board 16. The solder 44 is supplied in advance to the position of the pad 25. The solder ball 29 is mounted on the upper side of the solder 44 that is supplied to the pad 25, and thereby the semiconductor package 17 is mounted on the printed wiring board 16.

The printed wiring board 16, on which the semiconductor package 17 is mounted, is delivered into a reflow furnace for heat treatment. In the reflow furnace, heat treatment is performed to melt the solder 44 and solder ball 29. With the melting of the solder 44 and solder ball 29, the semiconductor package 17 is electrically connected to the printed wiring board 16. After the completion of solder bonding, the adhesive 31 is applied to the four corner portions 17a of the semiconductor package 17.

The applied adhesive 31 is cured through a curing process which is conducted, e.g. at a temperature of 80° or more for a time period of 20 minutes or more. By the curing of the adhesive 31, the mounting process of the semiconductor package 17 is completed.

The adhesive 31 may be composed of a two-liquid mixture type resin, instead of the thermosetting resin. This adhesive 31 can be cured, for example, by mixing two liquids for 10 seconds or more and leaving the mixture for five minutes at room temperature. Aside from the two-liquid mixture type adhesive, it is possible to adopt a resin adhesive, which is used in such a manner that an adhesive is first applied and a curing agent, for instance, is sprayed to the adhesive to facilitate curing of the adhesive. In the case of the adhesive that is of the type in which the curing agent is sprayed, the adhesive, to which the curing agent has been sprayed, is left for 30 seconds or more at room temperature. Thereby, curing is facilitated.

It is also possible to compose the adhesive 31 of a thermosetting adhesive, and to perform melting of the solder 44 and curing of the adhesive at the same time in the reflow furnace. In this case, it is preferable to set such conditions that the melting of the solder 44 is followed by the curing of the adhesive 31. This makes it possible to perform fine adjustment, or alignment, of the semiconductor package 17, which is mounted with a positioning error, even after the solder 44 is melted. In this case, after the completion of the alignment, heat treatment is further continued to cure the adhesive 31.

In the present embodiment, the stepped portion 40 divides the area between the semiconductor package 17 and the printed wiring board 16 into the first region 42, to which the solder 44 for bonding the solder ball 29 and the pad 25 is supplied, and the second region 43 which is filled with the adhesive 31. Thereby, flow of the adhesive 31 into the first region 42 is suppressed, and damage to the solder-bonded part is prevented. In this case, the semiconductor package 17 is disposed such that the bonded part between the connection terminal and the pad 25 is located between the printed wiring board 16 and semiconductor package 17. Thus, the first region 42 is provided under the semiconductor package 17, and the second region 43 is provided at the outer peripheral portion 33 of the semiconductor package 17. In this manner, if the first region 42 and second region 43 are physically isolated, it becomes possible to effectively prevent flow of the adhesive 31 into the first region 42.

The stepped portion 40 is defined by the projection 41 that projects from the printed wiring board 16 toward the semiconductor package 17. The projection 41 functions as a partition, and prevents flow of the adhesive 31 into the first region 42. Further, by the provision of the projection 41, the contact area between the adhesive 31 and printed wiring board 16 increases, thereby ensuring firm connection between the semiconductor package 17 and printed wiring board 16. If silk screen printing is used, the projection 41 can easily be formed.

The adhesive 31 and stepped portion 40 are provided at the position corresponding to the corner portion 17a of the semiconductor package 17. Thus, the semiconductor package 17 and printed wiring board 16 can firmly be fixed at the corner portion 17a where a bending stress tends to concentrate. The second region 43 can be provided at a position which is away from the first region 42 and corresponds to the corner portion 17a of the semiconductor package 17, and flow of the adhesive 31 into the first region 42 can more effectively be prevented. The portable computer 11, which is an electronic apparatus including the printed circuit board 15, has an improved shock resistance.

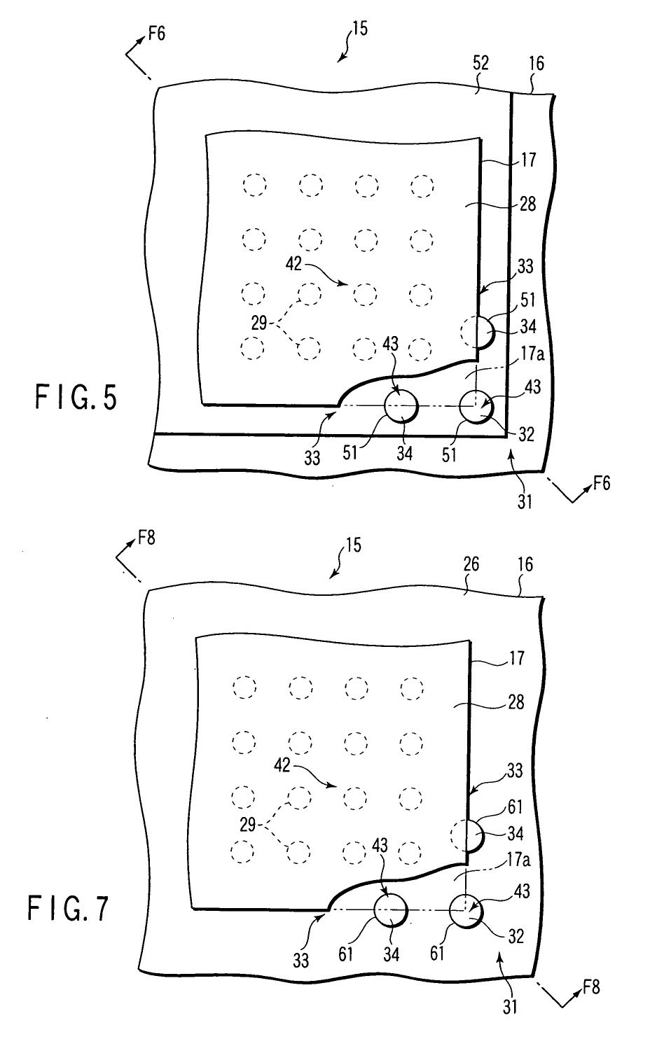

Next, referring to FIG. 5 and FIG. 6, a second embodiment of the printed circuit board 15 is described. The printed circuit board 15 of the second embodiment is the same as that of the first embodiment, except for the structure of the printed wiring board 16. Thus, common parts are denoted by like reference numerals, and a description thereof is omitted. In the printed circuit board 15 of the second embodiment, the stepped portion 40 is defined by a recess 51, which is provided at a position corresponding to the second region 43 on the printed wiring board 16.

Silk screen printing is effected on that part of the printed wiring board 16, where the semiconductor package 17 is mounted. As shown in FIG. 6, a silk-screen-print layer 52 is formed on the solder resist layer 26 by silk screen printing. In this case, the silk-screen-print layer 52 is not present on the second region 43 which is filled with the adhesive 31. Thereby, the recess 51 can be formed using silk screen printing. The adhesive 31 is filled in the recess 51.

According to the second embodiment, the stepped portion 40 is defined by the recess 51, which is provided at the position corresponding to the second region 43 on the printed wiring board 16. Thus, the recess 51 functions as a partition, suppresses flow of the adhesive 31 into the first region 42, and prevents damage to the solder-bonded part. Further, by the provision of the recess 51, the contact area between the adhesive 31 and printed wiring board 16 increases, thereby ensuring firm connection between the semiconductor package 17 and printed wiring board 16. Using silk screen printing, the recess 51 can easily be formed.

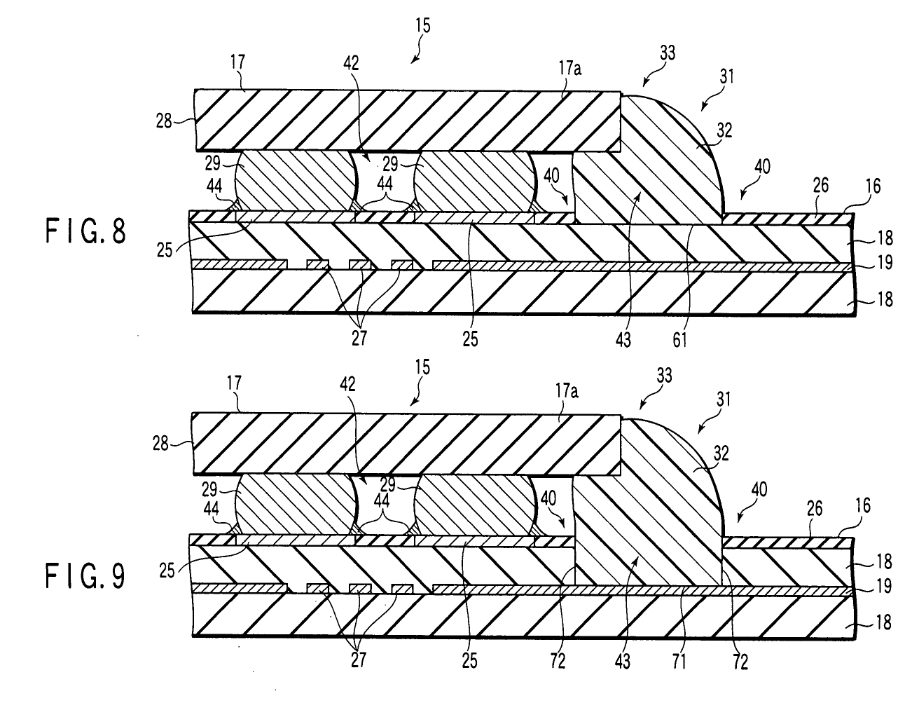

Next, referring to FIG. 7 and FIG. 8, a third embodiment of the printed circuit board 15 is described. The printed circuit board 15 of the third embodiment is the same as that of the second embodiment, except for the structure of a recess 61. Thus, common parts are denoted by like reference numerals, and a description thereof is omitted. The recess portion 61 of the third embodiment is formed by a solder resist which covers the printed wiring board 16.

As shown in FIG. 7, a solder resist layer 26 is formed on the printed wiring board 16. The solder resist layer 26 is formed, for example, by printing a solder resist. As shown in FIG. 8, the solder resist is printed such that the solder resist is not present in the second region 43. Thus, the second region 43 is formed as the recess 61. The adhesive 31 is filled in the recess 61. The solder resist layer 26 may be formed by attaching a sheet-like solder resist layer, or by exposing/developing a photosensitive material.

According to the third embodiment, the recess 61 suppresses flow of the adhesive 31 into the first region 42, and prevents damage to the solder-bonded part. Further, by the provision of the recess 61, the contact area between the adhesive 31 and printed wiring board 16 increases, thereby ensuring firm connection between the semiconductor package 17 and printed wiring board 16. Making use of solder resist, the recess 61 can easily be formed.

Next, referring to FIG. 9, a fourth embodiment of the printed circuit board 15 is described. The printed circuit board 15 of the fourth embodiment is the same as that of the third embodiment, except for the structure of a recess 71. Thus, common parts are denoted by like reference numerals, and a description thereof is omitted. As is shown in FIG. 9, the recess 71 of the fourth embodiment is defined by a via 72 which is a through hole penetrating the upper-side insulating layer 18. The via 72 is formed by applying a laser beam to the insulating layer 18 during the laminating process of the printed wiring board 16. In the fourth embodiment, the via 72 is formed as the second region 43. By filling the adhesive 31 in the via 72, the semiconductor package 17 is fixed to the printed wiring board 16. The formation of the via 72 is performed prior to the formation of the solder resist layer 26.

According to the fourth embodiment, the recess 71 suppresses flow of the adhesive 31 into the first region 42, and prevents damage to the solder-bonded part. Further, by the provision of the recess 71, the contact area between the adhesive 31 and printed wiring board 16 increases, thereby ensuring firm connection between the semiconductor package 17 and printed wiring board 16. If the recess 71 is formed as the via 72 by a laser, the recess 71 can easily be formed.

The printed circuit board of the present invention can be applied not only to the portable computer as described in the above embodiments, but also to other electronic apparatus such as a mobile information terminal.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board comprising:
a printed wiring board having a plurality of pads;
a circuit component which has a plurality of connection terminals corresponding to the pads and is mounted on the printed wiring board by soldering the connection terminals to the pads;
an adhesive which is filled between an outer peripheral portion of the circuit component and the printed wiring board and fixes the circuit component to the printed wiring board; and
a stepped portion which divides an area between the circuit component and the printed wiring board into a first region, to which a solder for bonding the connection terminal and the pad is supplied, and a second region in which the adhesive is filled.

2. The printed circuit board according to claim 1, wherein a bonded part between the connection terminal and the pad is located between the circuit component and the printed wiring board.

3. The printed circuit board according to claim 1, wherein the stepped portion is defined by a projection which projects from the printed wiring board toward the circuit component.

4. The printed circuit board according to claim 3, wherein the projection is formed by performing silk screen printing on the printed wiring board.

5. The printed circuit board according to claim 1, wherein the stepped portion is defined by a recess which is provided at a position corresponding to the second region on the printed wiring board.

6. The printed circuit board according to claim 5, wherein the recess is formed by performing silk screen printing on the printed wiring board.

7. The printed circuit board according to claim 5, wherein the recess is formed by a solder resist covering the printed wiring board.

8. The printed circuit board according to claim 5, wherein the recess is defined by a via formed in the printed wiring board.

9. The printed circuit board according to claim 8, wherein the via is formed by a laser.

10. The printed circuit board according to claim 1, wherein the adhesive and the stepped portion are provided at a position corresponding to a corner portion of the circuit component.

11. An electronic apparatus comprising:
a housing; and
a printed circuit board which is accommodated in the housing,
the printed circuit board including:
a printed wiring board having a plurality of pads;
a circuit component which has a plurality of connection terminals corresponding to the pads and is mounted on the printed wiring board by soldering the connection terminals to the pads;
an adhesive which is filled between an outer peripheral portion of the circuit component and the printed wiring board and fixes the circuit component to the printed wiring board; and
a stepped portion which divides an area between the circuit component and the printed wiring board into a first region, to which a solder for bonding the connection terminal and the pad is supplied, and a second region in which the adhesive is filled.
